(19) United States
(12) Patent Application Publication
(10) Pub. No.: US 2022/0115608 A1
(43) Pub. Date: Apr. 14, 2022

(54) FLEXIBLE SUBSTRATE MATERIAL, MANUFACTURING METHOD OF FLEXIBLE SUBSTRATE AND FLEXIBLE DISPLAY PANEL

(71) Applicant: TLC CHINA STAR OPTOELECTRONICS TECHNOLOGY CO., LTD., Shenzhen, Guangdong (CN)

(72) Inventor: Bao ZHA, Shenzhen, Guangdong (CN)

(21) Appl. No.: 16/765,803

(22) PCT Filed: Apr. 7, 2020
(86) PCT No.: PCT/CN2020/083539

§ 371 Date: May 20, 2020

(30) Foreign Application Priority Data
Mar. 19, 2020 (CN) 202010195541.X

(51) Int. Cl. H01L 51/00; D01D 5/00; D04H 1/728

(52) U.S. Cl. CPC H01L 51/0097; D01D 5/0007; D10B 2101/122; H01L 2251/5338; D04H 1/728

(57) ABSTRACT

A flexible substrate material is provided. The flexible substrate material includes a flexible base and graphene reinforcements dispersed in the flexible base, and the graphene reinforcements includes a graphene base and metal nanoparticles. The graphene base is a layer structure, and the metal nanoparticles are distributed on a surface of the layer structure of the graphene base. A manufacturing method thereof and a flexible display panel are also provided.

### FIELD OF INVENTION

The disclosure relates to the fields of display technology, and, in particular, to flexible substrate materials, manufacturing methods of flexible substrates, and flexible display panels.

### BACKGROUND OF INVENTION

With the rapid development of display technology, organic light-emitting diode (OLED) display technology and micro light-emitting diode (micro-LED) display technology are considered as a new generation of display technology that replaces liquid crystal display (LCD) technology due to the advantages of low power consumption, high brightness, ultra-high resolution, color saturation, fast response times, no requirement for a backlight, and self-illumination.

Technical problem: Currently, OLED display technology and micro-LED display technology still have some detailed problem to be improved. These detailed problems restrict the wide applications and developments of OLED display technology and micro-LED display technology. For example, both OLED display technology and micro-LED display technology adopt active light-emitting means. With the increase of resolution, the more color resistances demanded per unit area, the more heat generated per unit area. In order to ensure the normal operation of the display device, the generated heat has to be released in time to avoid the negative influence of the high temperature on the display device. The existing OLED flexible display panels and micro-LED flexible display panels generally use polyimide as the flexible substrate material, but the polyimide flexible substrate has a limited thermal conductivity.

Therefore, the development of flexible substrate materials with high thermal conductivity is one of the key factors to broaden the application ranges of OLED display technology and micro-LED display technology.

### SUMMARY OF DISCLOSURE

The disclosure provides a flexible substrate material, a manufacturing method of a flexible substrate and a flexible display panel. By modifying the flexible substrate material, the thermal conductivity of the flexible substrate is improved while the desired bending characteristics and deformation resistance ability of the flexible substrate are ensured, so as to improve the heat dissipation performance of the flexible display panel.

In a first aspect, embodiments of the present disclosure provide a flexible substrate material, including:

a flexible base; and

graphene reinforcements dispersed in the flexible base, and connected with the flexible base by chemical bonds; and each of the graphene reinforcements including a graphene base and metal nanoparticles, wherein the graphene base is a layer structure, and the metal nanoparticles are distributed on a surface of the layer structure of the graphene base.

The flexible substrate material is modified by mixing the graphene reinforcements in the flexible base. The graphene base has good thermal conductivity, and the thermal conductivity coefficient can be up to 5000 W/(m·K), thereby effectively improving the thermal conductivity of the flexible substrate. In addition, the graphene base adopts the layer structure, and the metal nanoparticles are distributed on the surface of the layer structure to prevent the agglomeration phenomenon in the flexible base between the layer structures of any two or more graphene bases.

In some embodiments, material of the flexible base is selected from one or more of polyethersulfone, polycarbonate, polyethylene terephthalate, polyethylene naphthalate, polyimide, polyarylate compound, and glass fiber reinforced plastic.

In some embodiments, the material of the flexible base is polyimide.

In some embodiments, material of the metal nanoparticles is selected from one or more of silver, copper, iron, titanium, nickel, and platinum.

In some embodiments, material of the metal nanoparticles is silver.

In some embodiments, the layer structure of the graphene base is a single layer, and the metal nanoparticles are distributed on at least one surface of the single layer.

In some embodiments, the layer structure of the graphene base is a composite layer, and the metal nanoparticles are distributed on at least one of an upper outermost surface and a lower outermost surface of the composite layer.

In a second aspect, embodiments of the present disclosure provide a manufacturing method of a flexible substrate, including following steps of:

preparing graphene reinforcements, each of the graphene reinforcements including a graphene base and metal nanoparticles, wherein the graphene base is a layer structure, and the metal nanoparticles are distributed on a surface of the layer structure of the graphene base;

mixing the graphene reinforcements with raw materials of a flexible base to prepare a flexible substrate material solution; and

forming a film by electrospinning the flexible substrate material solution, so as to obtain a flexible substrate, wherein the graphene reinforcements are dispersed in the flexible base.

In some embodiments, the step of preparing the graphene reinforcements includes steps of:

mixing a graphene oxide having a layer structure with a metal salt solution to obtain a first mixture;

adding a reductant to the first mixture to perform a reduction reaction to obtain a second mixture; and

filtering the second mixture to obtain a filter residue, wherein the filter residue is the graphene reinforcements.

In some embodiments, the metal salt solution is a silver nitrate solution, and the metal nanoparticles corresponding to the graphene reinforcements are silver nanoparticles.

In some embodiments, a concentration of the silver nitrate solution ranges from 150 to 200 g/mol.

In some embodiments, a mass ratio of the graphene oxide having the layer structure and the silver nitrate solution is 50-60:1.

In some embodiments, the reductant is D-glucose.

In some embodiments, a molar ratio of the D-glucose and the silver nitrate solution is 1:1.2.

In some embodiments, a reaction temperature of the reduction reaction ranges from 100 to 120° C., thereby avoiding damage to the reaction system caused by high temperature.

In some embodiments, a reaction time of the reduction reaction ranges from 10 to 12 hours, thereby ensuring that the reduction reaction being sufficient.

In some embodiments, the step of preparing the flexible substrate material solution includes steps of:

mixing the graphene reinforcements with a dispersion solution to prepare a graphene dispersion solution; and

adding raw materials for preparing the flexible base into the graphene dispersion solution, and mixing uniformly to fully react to obtain the flexible substrate material solution.

In some embodiments, the dispersion solution is tetrahydrofuran, the raw materials of the flexible base are dianhydride and diamine, and preparing the flexible substrate material solution includes corresponding steps of:

uniformly dispersing the graphene reinforcements in the tetrahydrofuran to obtain the graphene dispersion solution; and

adding dianhydride and diamine both having a mass ratio of 1:1 into the graphene dispersion solution, and mixing uniformly to fully react to obtain the flexible substrate material solution.

In some embodiments, a thickness of the flexible substrate ranges from 10 to 1000 microns.

In a third aspect, embodiments of the present disclosure provide a flexible display panel, including: a flexible substrate manufactured by using the flexible substrate manufacturing method described in the second aspect.

Beneficial effect: The flexible substrate material provided by the disclosure is a composite material obtained by mixing graphene reinforcements in a flexible polymer material. The flexible substrate material has desired bending characteristics, deformation resistance ability and high thermal conductivity, thereby greatly improving the heat dissipation performance of the flexible substrate. Because the graphene base has a strong π-π conjugated bond, it is easy to agglomerate in the polymer material, so it is difficult to uniformly disperse in the polymer material. Therefore, the present disclosure, metal nanoparticles are further distributed on the surfaces of the layer structures of the graphene bases to form a point-to-plane dispersion effect (that is, the metal nanoparticles prevent any two or more layer structures of graphene bases from contacting each other and aggregation), thereby effectively preventing the occurrence of agglomeration.

The manufacturing method of a flexible substrate provided by the present disclosure includes steps of: preparing graphene reinforcements; preparing a flexible substrate material solution; and forming the flexible substrate material solution into a film by electrospinning to obtain a flexible substrate. The manufacturing method has the advantages of few procedures, simple operation, easy control, and easy realization of industrial production.

The flexible display panel provided by the present disclosure, including the flexible substrate prepared by the flexible substrate manufacturing method according to the present disclosure. The flexible substrate has excellent heat dissipation performance, meets the high heat dissipation performance requirements of OLED and micro-LED display technologies, and has the advantages of broadening the application scope of OLED and micro-LED display technologies to promote the rapid development of OLED and micro-LED display technologies.

### DRAWINGS

FIG. 1 is a schematic structural view of a flexible substrate material according to an embodiment of the present disclosure.

FIG. 2 is a schematic flow chart of a manufacturing method of a flexible substrate according to an embodiment of the present disclosure.

FIG. 3 is a schematic flow chart of step S1 of FIG. 2.

FIG. 4 is a schematic flow chart of step S2 of FIG. 2.

### DETAILED DESCRIPTION OF EMBODIMENTS

In order to make the above-mentioned objects, features and advantages of the present disclosure more apparent and understandable, the preferred embodiments of the present disclosure are described below in conjunction with the drawings, which are described in detail below. Furthermore, the directional terms mentioned in the present disclosure, such as “up”, “down”, “front”, “rear”, “left”, “right”, “inner”, “outer”, “side”, etc., refer only to the directions in the drawings. Therefore, the directional language is used to illustrate and understand the disclosure, rather than to limit the disclosure.

Specifically, in a first aspect, an embodiment of the present disclosure provides a flexible substrate material, including:

A flexible base (i.e. flexible matrix); and

Graphene reinforcements are dispersed in the flexible base and are connected with the flexible base by chemical bonds. Each of the graphene reinforcements includes a graphene base and metal nanoparticles. The graphene base is a layer structure, and the metal nanoparticles are distributed on at least one surface of the layer structure of the graphene base.

Specifically, the flexible substrate material provided in the embodiments of the present disclosure is a composite material. By modifying a traditional flexible substrate material (that is, flexible base), the flexible base is mixed with the graphene reinforcements, thereby greatly improving the thermal conductivity of the flexible substrate material.

Specifically, each of the graphene base has a layer structure. Because the graphene base has outstanding thermal conductivity and mechanical properties, mixing the graphene into the flexible base can greatly improve the thermal conductivity of the flexible substrate.

It should be noted that because the graphene base has a strong π-π conjugated bond, agglomeration phenomenon is likely to occur between the layer structures of the graphene bases in the polymer material (such as flexible base), it is difficult to uniformly disperse in the polymer material. Therefore, the metal nanoparticles distributed on the at least one surface of each of the layer structures of the graphene bases to obtain the graphene reinforcements can greatly weaken the π-π conjugated bonding force and form a point-to-plane dispersion effect (i.e., the metal nanoparticles prevent any two or more layer structures of the graphene bases from contacting and agglomerating with each other), thereby promoting the graphene reinforcements to be uniformly dispersed in the flexible base.

In some embodiments, a lateral length dimension of the layer structure of the graphene base generally ranges from 2 to 70 microns and a thickness ranges from 2 to 10 nanometers, and a single layer structure of the graphene base may be in a form of a single layer, or in a form of a composite layer. The form of the composite layer may be formed by laminating 2, 5, 10, 20 or 30 layers. When a single layer structure of the graphene base exists as a single layer, the metal nanoparticles are distributed on at least one surface of the single layer. When a single layer structure of the graphene base exists as a composite layer, the metal nanoparticles are distributed on at least one of an upper outermost surface and a lower outermost surface of the composite layer to prevent any two adjacent layer structures from contacting and agglomerating with each other.

In some embodiments, the flexible base is selected from one or more of polyimide, polyethersulfone, polycarbonate, polyethylene terephthalate, polyethylene naphthalate, polyarylate compound, and glass fiber reinforced plastic. The embodiment of the present disclosure is preferably polyimide. Polyimide is a type of polymer wherein imide groups of repeatable units are used as structural characteristic groups. Polyimide has the advantages of desired mechanical properties, high insulating properties, high temperature resistance, corrosion resistance, and small dielectric loss, and is one of the polymer materials with ideal comprehensive properties.

In some embodiments, material of the metal nanoparticles is selected from one or more of silver, copper, iron, titanium, nickel, and platinum. The embodiment of the present disclosure is preferably silver. Nano-silver particles have the advantages of desired stability, low cost, easy acquisition, and simple production process.

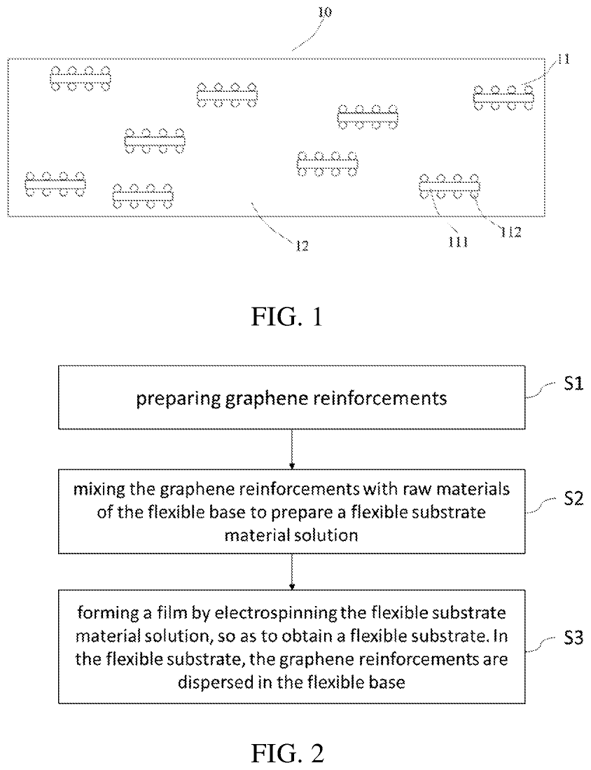

For example: a flexible substrate material 10 specifically is polyaimide 12 mixed with graphene reinforcements 11, the graphene reinforcements 11 are uniformly dispersed in the polyimide 12, and are connected with the polyimide 12 by chemical bonds. Referring to FIG. 1, each of the graphene reinforcements 11 includes a graphene base 111 and nano-silver particles 112. The graphene base 111 is a graphene having a layer structure, and the nano-silver particles 112 are distributed on at least one surface (for example, upper surface and lower surface) of the graphene base 111. The flexible substrate material 10 can be used for preparing and/or being a flexible substrate of an organic light-emitting diode (OLED) flexible display panel and/or a micro-LED flexible display panel to improve the heat dissipation performance of the flexible display panel for the organic light-emitting diode elements and micro light-emitting diode elements thereon.

In a second aspect, an embodiment of the present disclosure provides a manufacturing method of a flexible substrate. Material of the flexible substrate is the flexible substrate material described in the first aspect. Referring to FIG. 2, the method includes:

A step S1 of preparing graphene reinforcements.

Specifically, each of the graphene reinforcements includes a graphene base and metal nanoparticles. The graphene base is at least one layer structure, and the metal nanoparticles are distributed on a surface of the layer structure of the graphene base.

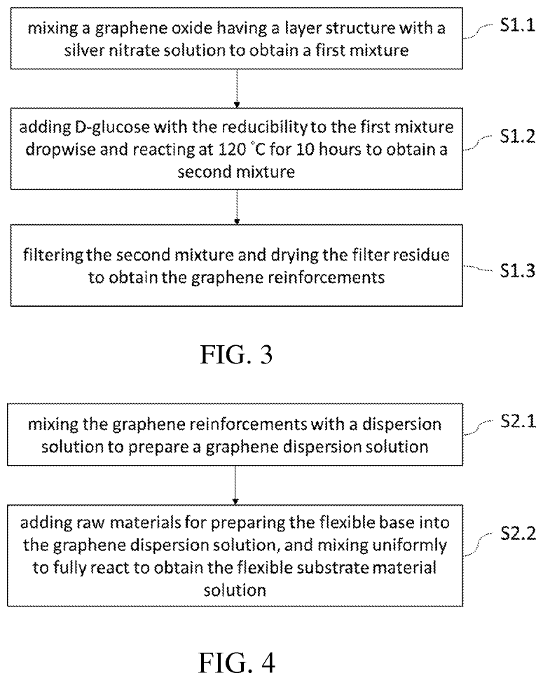

In some embodiments, referring to FIG. 3, the step S1 includes:

A step S1.1 of mixing a graphene oxide having a layer structure with a metal salt solution to obtain a first mixture.

A step S1.2. of adding a reductant to the first mixture to perform a reduction reaction to obtain a second mixture.

Specifically, the graphene reinforcements are prepared by an oxidation-reduction reaction method. Raw materials for preparing the graphene reinforcements are a graphene oxide and a metal salt solution, and both are mixed to obtain a first mixture. The graphene oxide is a micro layer structure, its unique two-dimensional structure and rich oxygen-containing functional groups enable to uniformly and stably disperse the graphene oxide in the metal salt solution, and the graphene oxide has strong adsorption capacity for the metal cations in the metal salt solution, so as to promote the metal cations in the metal salt solution to attach to the graphene oxide. Then, under the action of the reductant, the graphene oxide and the metal salt solution undergo a reduction reaction, so that the metal nanoparticles are uniformly distributed on the surface of the layer structures of the graphene bases, thereby generating the graphene reinforcements mixed with the metal nanoparticles.

In some embodiments, the reaction temperature of the reduction reaction ranges from 100 to 120° C., and the reaction time ranges from 10 to 12 hours, to ensure sufficient reduction reaction and avoid damage to the reaction system at high temperature.

A step S1.3 of filtering the second mixture to obtain a filter residue, and the filter residue is the graphene reinforcements.

Specifically, the second mixture is filtered, and the filter residue is performed a drying treatment, such as performing a heat drying operation to obtain the graphene reinforcements.

For example, when the metal nanoparticles are silver nanoparticles, the step S1 includes:

A step S1.1 of mixing a graphene oxide having a layer structure with a silver nitrate solution to obtain a first mixture.

Specifically, the graphene oxide having the layer structure and the silver nitrate solution are mixed according to a mass ratio of 50-60:1, and a concentration of the silver nitrate solution ranges from 150 to 200 g/mol.

A step S1.2 of adding D-glucose with the reducibility to the first mixture dropwise and reacting at 120° C. for 10 hours to obtain a second mixture.

Specifically, the D-glucose is added to the first mixture dropwise until the molar ratio of D-glucose to the silver nitrate solution in the reaction system reaches 1:1.2, the addition of D-glucose is stopped.

A step S1.3 of filtering the second mixture and drying the filter residue to obtain the graphene reinforcements.

A step S2 of mixing the graphene reinforcements with raw materials of the flexible base to prepare a flexible substrate material solution.

Specifically, the flexible substrate material solution is a flexible base solution mixed with the graphene reinforcements, and the graphene reinforcements are uniformly dispersed in the flexible base.

In some embodiments, referring to FIG. 4, the step of preparing the flexible substrate material solution includes:

A step S2.1 of mixing the graphene reinforcements with a dispersion solution to prepare a graphene dispersion solution.

A step S2.2 of adding raw materials for preparing the flexible base into the graphene dispersion solution, and mixing uniformly to fully react to obtain the flexible substrate material solution.

Specifically, the graphene reinforcements are uniformly dispersed in a specific dispersion solution to obtain the graphene dispersion solution. The specific dispersion solution needs to satisfy the conditions: the compatibility with graphene reinforcements is ideal; it cannot react with the graphene reinforcements, the flexible base, and the raw materials for preparing the flexible base.

For example, the dispersion solution is tetrahydrofuran and the raw materials of the flexible base are dianhydride and diamine (i.e., the flexible base is polyimide), and the step of preparing the flexible substrate material solution includes:

A step S2.1 of uniformly dispersing the graphene reinforcements in the tetrahydrofuran to obtain the graphene dispersion solution.

A step S2.2 of adding dianhydride and diamine both having a mass ratio of 1:1 into the graphene dispersion solution, and mixing uniformly to fully react to obtain the polyimide flexible substrate material solution mixed with the graphene reinforcements.

Specifically, the chemical reaction formula for the reaction of dianhydride and diamine to form polyimide is as follows:

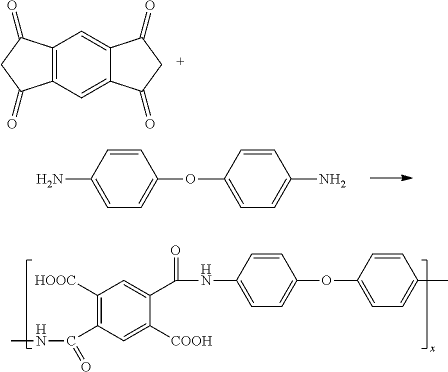

A step S3 of forming a film by electrospinning the flexible substrate material solution, so as to obtain a flexible substrate. In the flexible substrate, the graphene reinforcements are dispersed in the flexible base.

Specifically, the electrospinning method is a special fiber manufacturing process in which a polymer solution or a melt mass is subjected to jet spinning in a strong electric field to produce nanometer-sized polymer filaments. The electrospinning method is a special form of electrostatic atomization of polymer fluid. Under the action of electric field, the liquid drop at the needle head changes from a sphere to a cone, and extends from the tip of the cone to obtain a fiber filament. That is, when the electric field force is large enough, the polymer liquid drop can overcome the surface tension to form a jet stream, and the charged polymer jet will be stretch, and finally solidified to form a fiber. The electrospinning method has the advantages of simple operation, low cost and controllable process. The prepared flexible substrate has the characteristics of uniform fiber diameter distribution, large specific surface area and large porosity, which improves the heat dissipation effect of the flexible substrate.

It should be noted that the embodiment of the disclosure does not specifically limit the process parameters of the electrospinning method, and can be selected according to the actual needs.

Specifically, for example, the flexible substrate material solution can be formed on a temporary carrier by electrospinning to obtain a flexible substrate attached on the carrier, and then the flexible substrate can be peeled off from the carrier for later use. The temporary carrier is a reusable rigid base plate or a flexible base plate to provide a temporary support surface. The rigid base plate can be made of glass, metal and other materials. The flexible base plate can be made of plastic and other materials, but it needs to have enough support thickness, for example, a prefer carrier of an embodiment of the present disclosure is a glass base plate.

In some embodiments, a thickness of the flexible substrate ranges from 10 to 1000 microns, which can be used as flexible substrates for OLED flexible display panels and micro-LED flexible display panels, and their heat resistance and heat conduction characteristics are significantly superior to traditional flexibility substrates.

In a third aspect, an embodiment of the present disclosure provides a flexible display panel, including: a flexible substrate manufactured by using the manufacturing method of the flexible substrate described in the second aspect.

For example, the flexible display panel may be an OLED flexible display panel, including: a flexible substrate, a thin film transistor array layer sequentially stacked from bottom to top, and OLED display units (such as OLED display units having red color resistance, green color resistance, and blue color resistance), an encapsulation layer and a protective cover plate. The flexible substrate is a flexible substrate manufactured by the manufacturing method of the flexible substrate according to the second aspect of the present disclosure, and other layers or components can all use the existing technology products. The OLED flexible display panel can be provided with other functional layers according to actual needs, such as: a polarizer, a protective layer, and a touch layer, etc. The above functional layers can all use the existing technology products.

For example, the flexible display panel may be a micro-LED flexible display panel, including: a flexible substrate, an integrated circuit layer and a LED matrix layer sequentially stacked from bottom to top, the flexible substrate adopts a flexible substrate manufactured by the manufacturing method of the flexible substrate according to the second aspect of the present disclosure, other composition layers or components may use the existing products.

The flexible display panel provided according to a third aspect of the present disclosure can be applied to a variety of display devices. Specifically, the display device can be any products or components with display functions, such as, mobile phones, tablet computers, notebooks, digital cameras, digital video cameras, smart wearable devices, smart electronic scales, vehicle displays or televisions. The smart wearable devices can be smart bracelets, smart watches or smart glasses, etc.

The present disclosure has been described by the above-mentioned related embodiments, but the above-mentioned embodiments are only examples for implementing the present disclosure. It must be pointed out that the disclosed embodiments do not limit the scope of the present disclosure. Conversely, modifications and equivalent arrangements included in the spirit and scope of the claims are all included in the scope of the present disclosure.

1. A flexible substrate material, comprising:
a flexible base; and
graphene reinforcements dispersed in the flexible base, and connected with the flexible base by chemical bonds; and each of the graphene reinforcements comprising a graphene base and metal nanoparticles, wherein the graphene base is a layer structure, and the metal nanoparticles are distributed on a surface of the layer structure of the graphene base.

2. The flexible substrate material according to claim 1, wherein material of the flexible base is selected from one or more of polyimide, polyethersulfone, polycarbonate, polyethylene terephthalate, polyethylene naphthalate, polyarylate compound, and glass fiber reinforced plastic.

3. The flexible substrate material according to claim 2, wherein the material of the flexible base is polyimide.

4. The flexible substrate material according to claim 1, wherein material of the metal nanoparticles is selected from one or more of silver, copper, iron, titanium, nickel, and platinum.

5. The flexible substrate material according to claim 1, wherein material of the metal nanoparticles is silver.

6. The flexible substrate material according to claim 1, wherein the layer structure of the graphene base is a single layer, and the metal nanoparticles are distributed on at least one surface of the single layer.

7. The flexible substrate material according to claim 1, wherein the layer structure of the graphene base is a composite layer, and the metal nanoparticles are distributed on at least one of an upper outermost surface and a lower outermost surface of the composite layer.

8. A manufacturing method of a flexible substrate, comprising following steps of:
preparing graphene reinforcements, each of the graphene reinforcements comprising a graphene base and metal nanoparticles, wherein the graphene base is a layer structure, and the metal nanoparticles are distributed on a surface of the layer structure of the graphene base;
mixing the graphene reinforcements with raw materials of a flexible base to prepare a flexible substrate material solution; and
forming a film by electrospinning the flexible substrate material solution, so as to obtain a flexible substrate, wherein the graphene reinforcements are dispersed in the flexible base.

9. The manufacturing method of the flexible substrate according to claim 8, wherein the step of preparing the graphene reinforcements comprises steps of:
mixing a graphene oxide having a layer structure with a metal salt solution to obtain a first mixture;
adding a reductant to the first mixture to perform a reduction reaction to obtain a second mixture; and
filtering the second mixture to obtain a filter residue, wherein the filter residue is the graphene reinforcements.

10. The manufacturing method of the flexible substrate according to claim 9, wherein the metal salt solution is a silver nitrate solution, and the metal nanoparticles corresponding to the graphene reinforcements are silver nanoparticles.

11. The manufacturing method of the flexible substrate according to claim 10, wherein a concentration of the silver nitrate solution ranges from 150 to 200 g/mol.

12. The manufacturing method of the flexible substrate according to claim 11, wherein a mass ratio of the graphene oxide having the layer structure and the silver nitrate solution is 50-60:1.

13. The manufacturing method of the flexible substrate according to claim 10, wherein the reductant is D-glucose.

14. The manufacturing method of the flexible substrate according to claim 13, wherein a molar ratio of the D-glucose and the silver nitrate solution is 1:1.2.

15. The manufacturing method of the flexible substrate according to claim 14, wherein a reaction temperature of the reduction reaction ranges from 100 to 120° C.

16. The manufacturing method of the flexible substrate according to claim 15, wherein a reaction time of the reduction reaction ranges from 10 to 12 hours.

17. The manufacturing method of the flexible substrate according to claim 8, wherein the step of preparing the flexible substrate material solution comprises steps of:
mixing the graphene reinforcements with a dispersion solution to prepare a graphene dispersion solution; and
adding raw materials for preparing the flexible base into the graphene dispersion solution, and mixing uniformly to fully react to obtain the flexible substrate material solution.

18. The manufacturing method of the flexible substrate according to claim 17, wherein the dispersion solution is tetrahydrofuran, the raw materials of the flexible base are dianhydride and diamine, and preparing the flexible substrate material solution comprises corresponding steps of:
uniformly dispersing the graphene reinforcements in the tetrahydrofuran to obtain the graphene dispersion solution; and
adding dianhydride and diamine both having a mass ratio of 1:1 into the graphene dispersion solution, and mixing uniformly to fully react to obtain the flexible substrate material solution.

19. The manufacturing method of the flexible substrate according to claim 8, wherein a thickness of the flexible substrate ranges from 10 to 1000 microns.

20. A flexible display panel, comprising: a flexible substrate, and material of the flexible substrate comprising:
a flexible base; and
graphene reinforcements dispersed in the flexible base and connected with the flexible base by chemical bonds; and each of the graphene reinforcements comprising a graphene base and metal nanoparticles, wherein the graphene base is a layer structure, and the metal nanoparticles are distributed on a surface of the layer structure of the graphene base;
wherein the material of the flexible substrate is polyimide, material of the metal nanoparticles is silver, wherein the layer structure of the graphene base is a single layer, and the metal nanoparticles are distributed on at least one surface of the single layer; or the layer structure of the graphene base is a composite layer, and the metal nanoparticles are distributed on at least one of an upper outermost surface and a lower outermost surface of the composite layer.
